(19) United States
(12) Patent Application Publication
(10) Pub. No.: US 2006/0202320 A1
(43) Pub. Date: Sep. 14, 2006

(54) Power semiconductor package

(76) Inventor: Christopher P. Schaffer, Fallbrook, CA (US)

Correspondence Address: OSTROLENK FABER GERB & SOFFEN, 1180 AVENUE OF THE AMERICAS, NEW YORK, NY, 100368403, US

(21) Appl. No.: 11/370,716

(22) Filed: Mar. 8, 2006

Related U.S. Application Data
(60) Provisional application No. 60/660,399, filed on Mar. 10, 2005.

(51) Int. Cl. H01L 23/48

(52) U.S. Cl. 257/690

(57) ABSTRACT

A semiconductor package that includes a semiconductor device and a lead frame having a first lead frame portion and a second lead frame portion, each lead frame portion including a plurality of fingers and a lead pad, each finger being electrically connected to a respective electrode of the semiconductor device.

### RELATED APPLICATION

This application is based on and claims benefit of U.S. Provisional Application No. 60/660,399, filed on Mar. 10, 2005, entitled PACKAGING STRUCTURE FOR GALLIUM NITRIDE DEVICES, to which a claim of priority is hereby made and the disclosure of which is incorporated by reference.

### BACKGROUND OF THE INVENTION

The present invention relates to semiconductor packages.

It is well known that to incorporate a semiconductor device within a circuit, such a power supply or power regulation circuit, the semiconductor device must be packaged. Packaging, however, can consume a relatively large area on a circuit board. Thus, chip-scale type of packaging has been developed in order to reduce the area that is consumed by a package.

In one variety of chip-scale package, a power electrode of the semiconductor device is readied for direct connection by a conductive adhesive to a conductive pad on a circuit board. While this concept currently contributes to the reduction of the size of a semiconductor package, it may not be a feasible concept in the future. Specifically, as the size of the die decreases with the improvement of die processing technology and materials, the physical dimensions of the electrodes of the die also decrease. The reduction in the dimension of the electrodes combined with the improvement in the current carrying density of the semiconductor devices may lead to undesirable results such as premature damage to the conductive adhesive due to the enlarged current density passing through the connection point, high resistance due to the reduced connection cross-section, and difficulty in assembling the die through direct connection of the electrodes to a conductive pad on a circuit board due again to the reduced size of the electrode.

It is, therefore, desirable to have a packaging solution for small die that can overcome the potential problems arising from the reduction in the size of the electrodes.

### SUMMARY OF THE INVENTION

A semiconductor package according to the present invention includes a semiconductor die having a first plurality of power electrodes and a second plurality of power electrodes disposed on a major surface thereof, each first power electrode being spaced from and opposite to a second power electrode, a lead frame including a first lead portion and a second lead portion, the first lead portion including a plurality of spaced first fingers each electrically and mechanically connected to a respective first power electrode and a first lead pad electrically connected to said spaced first fingers and having a first external surface configured for external electrical connection, and the second lead portion including a plurality of spaced second fingers each electrically and mechanically connected to a respective second power electrode and a second lead pad electrically connected to the spaced second fingers and having a second external surface configured for external electrical connection, and molded housing encapsulating at least the semiconductor die and portions of the first lead pad and the second lead pad, wherein the first external surface and the second external surface are exposed through the molded housing.

According to an aspect of the present invention, the fingers allow for connection to the electrodes of the power semiconductor device while the external connection surface of each lead pad, for example, allows for an enlarged area for external connection to a respective conductive pad of a circuit board. The enlarged connection area allows for easier assembly of the package while reducing the current density through the connection between the package and the conductive pad.

A lead frame in a package according to the present invention may further include at least one more lead for connection to the control electrode of the semiconductor device, or two leads each for connection to a respective control electrode (e.g. when the device is bidirectional), or one to serve as a lead connection to a control electrode and the other to serve as a current sense lead. In the preferred embodiment of the present invention, the connection surfaces of all the leads may be coplanar for easier assembly on a substrate.

The semiconductor device in a package according to the present invention may be a III-nitride based power semiconductor device such as a schottky device, a HEMT, a MOSHFET, a MISHFET, or the like.

A package according to another embodiment of the present invention includes a heat spreader thermally connected to the semiconductor device which is exposed through the molded housing. Preferably, the exposed surface of the heat spreader is coplanar with the external surface of the molded housing through which it is exposed.

Other features and advantages of the present invention will become apparent from the following description of the invention which refers to the accompanying drawings.

### BRIEF DESCRIPTION OF THE FIGURES

FIG. 1 illustrates a top plan view of a semiconductor die used in a package according to the first embodiment of the present invention.

FIG. 2 illustrates a top plan view of a lead frame used in a package according to the first embodiment of the present invention.

FIG. 3 illustrates a bottom plan view of a package according to the first embodiment of the present invention.

FIG. 4 illustrates a cross-sectional view along line 4-4 in FIG. 3 viewed in the direction of the arrows.

FIG. 5 illustrates a cross-section view along line 5-5 in FIG. 3 viewed in the direction of the arrows.

FIG. 6 illustrates a perspective view of a lead frame and die (in an unassembled state) used in a package according to the second embodiment of the present invention.

FIG. 7 illustrates a perspective view of a lead frame and die (in an assembled state) used in a package according to the second embodiment of the present invention.

FIG. 8 illustrates a perspective view of a bottom portion of a package according to the second embodiment of the present invention.

FIG. 9 illustrates the assembly of FIG. 7 with an optional heat spreader.

FIG. 10 illustrates a top perspective view of a package according to an alternative embodiment of the present invention.

FIGS. 11A-11D illustrate an additional embodiment of the present invention.

FIGS. 12A-12D illustrate a further embodiment of the present invention.

FIGS. 13A-13D illustrate a further embodiment of the present invention.

### DETAILED DESCRIPTION OF EMBODIMENTS

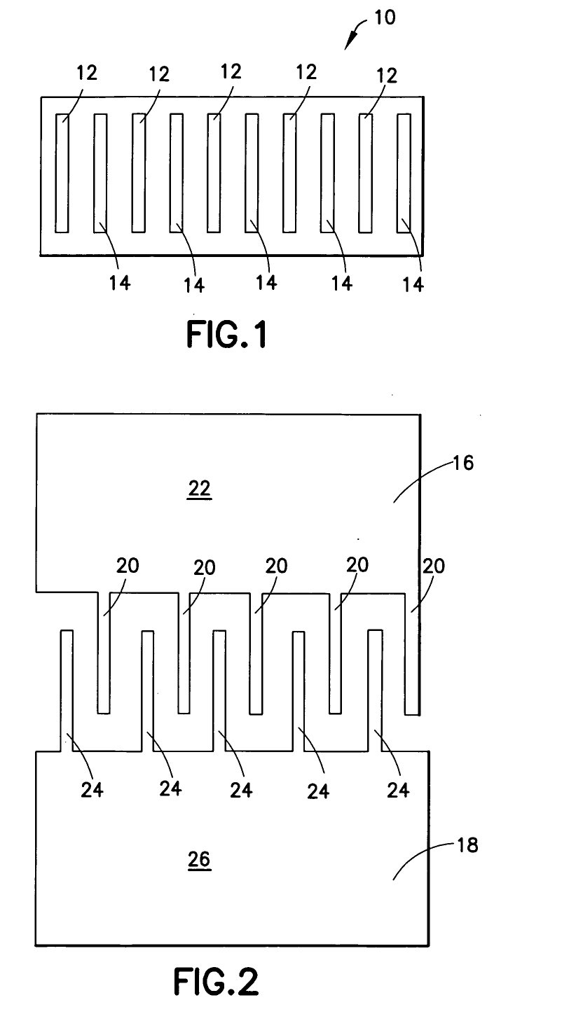

Referring to FIG. 1, a power semiconductor device 10 in a package according to the present invention includes a plurality of elongated first power electrodes 12, and a plurality of elongated second power electrodes 14. As shown, each first power electrode is spaced from but opposite to a second power electrode. Thus, first power electrodes 12 and second power electrodes 14 are alternately arranged.

Referring next to FIG. 2, a package according to the present invention further includes a lead frame having at least first lead portion 16 and second lead portion 18. First lead portion 16 includes a plurality of spaced first fingers 20 extending from a first lead pad 22, and second lead portion 18 includes a plurality of spaced second fingers 24 extending from second lead pad 26.

According to an aspect of the present invention, each first finger 20 is electrically and mechanically connected to a first power electrode 12 by a conductive adhesive such as solder or a conductive epoxy, and each second finger 24 is electrically and mechanically connected to a second power electrode 14 by a conductive adhesive such as solder or conductive epoxy. The assembly of the semiconductor die 10 and lead frame portions 16, 18 is then overmolded with mold compound. The mold compound encapsulates die 10 and at least portions of the lead frame, thus serving as the molded housing of the package. Note that preferably fingers 12, 14 are recessed allowing mold compound to encapsulate the same.

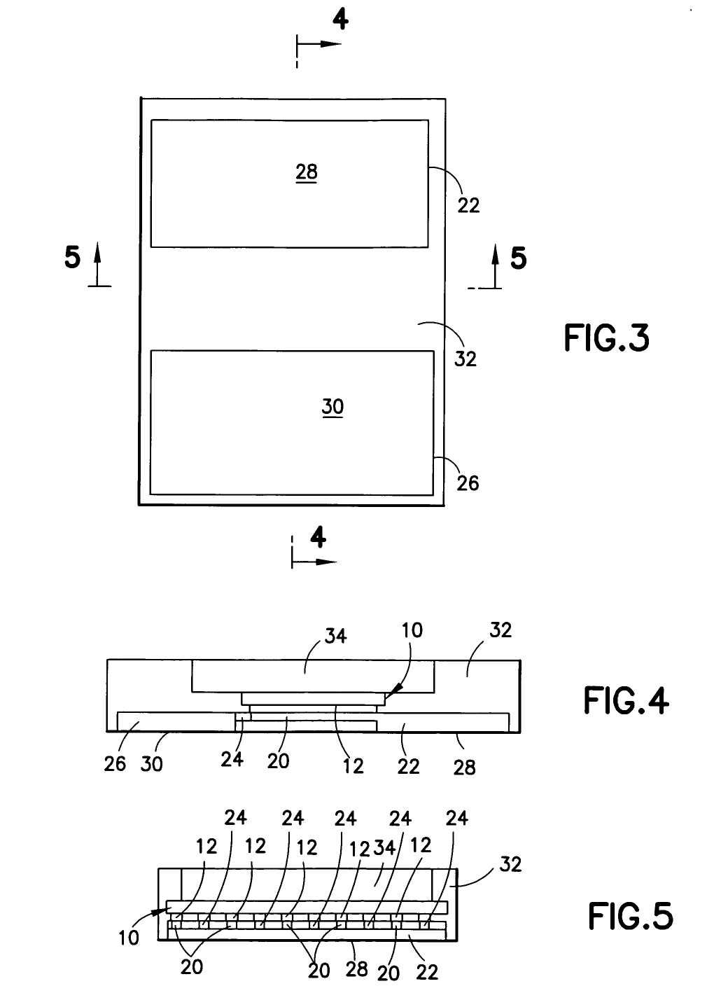

Referring next to FIGS. 3, 4 and 5, according to another aspect of the present invention, first lead pad 22 includes first external surface 28 and second lead pad 26 includes second external surface 30. Each external surface is exposed through molded housing 32 and is configured for external connection by preferably a conductive adhesive (e.g. solder or conductive epoxy) or the like to a corresponding conductive pad on, for example, a circuit board. Preferably, first and second external connection surfaces 28, 30 are coplanar. Furthermore, preferably, the surface of the die opposite power electrodes 12, 14 is electrically inactive and may be thermally connected either through direct connection or through an intermediate thermal body to heat spreader 34. Note that, preferably, the exterior surface of heat spreader 34 is coplanar with the external surface of molded housing 32 through which heat spreader 34 is exposed.

Semiconductor die 10 in a package according to the first embodiment may be a schottky device, such as a heterojunction variety III-nitride schottky device based on the InAlGan system, for example, a GaN-based device. A package according to the present invention is not limited to a schottky device, however.

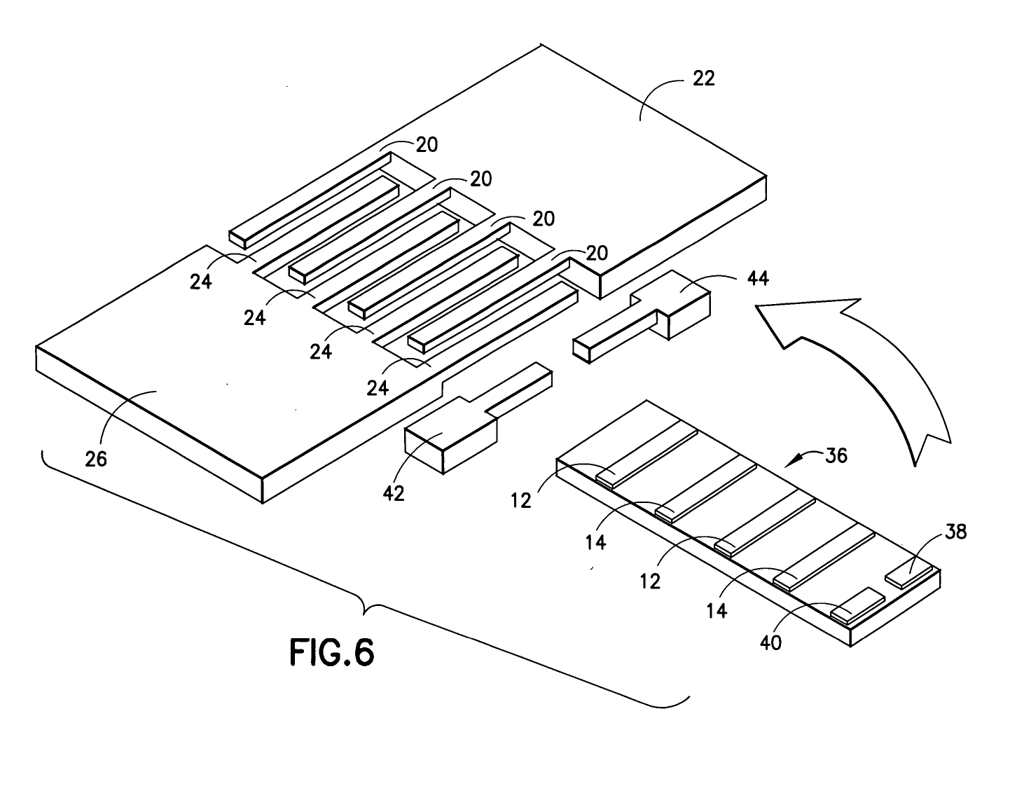

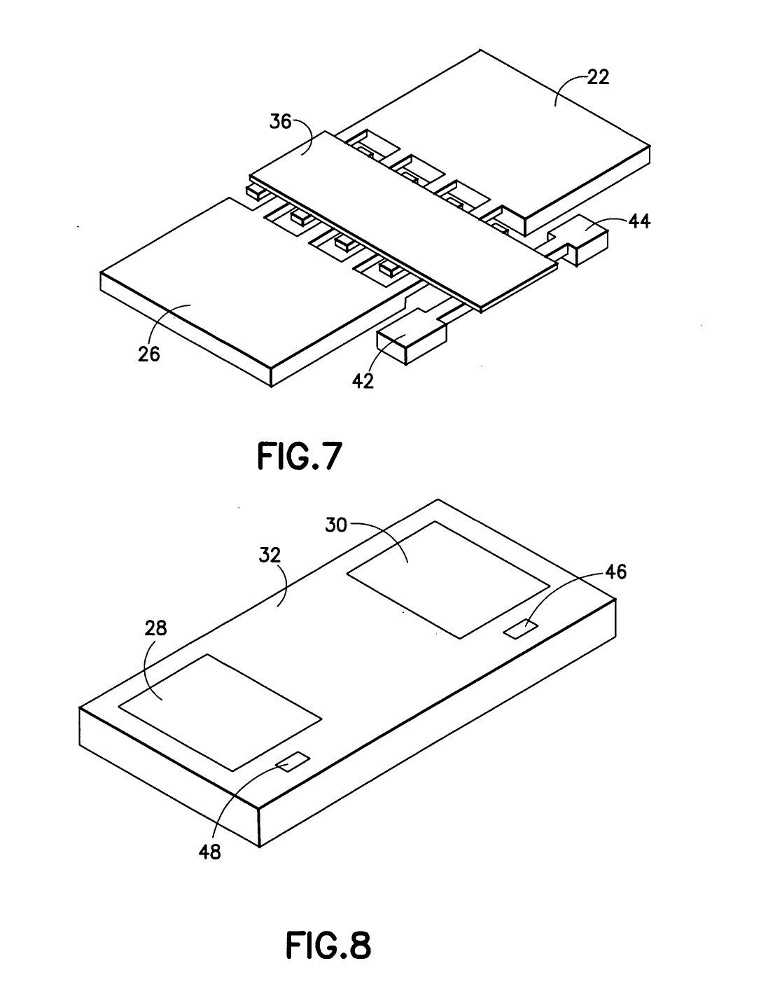

Referring for example to FIG. 6, in a second embodiment of the present invention, semiconductor die 36 may include more electrodes in addition to first and second power electrodes 12, 14. For example, semiconductor die 36 may include two more electrodes 38, 40. In one embodiment, electrodes 38, 40 may each be a control electrode. Such a device may be, for example, a bidirectional device. In another embodiment, electrode 38 may be a control electrode and electrode 40 may be a current sense electrode. In either case, the lead frame may further include a lead 42 that is electrically connected to electrode 36 and another lead 44 that is electrically connected to electrode 40. Once die 36 is assembled onto the lead frame (see FIG. 7), the assembly is overmolded with mold compound. Thus, as seen in FIG. 8, connection surfaces 28, 30 of lead pads 22, 24 are exposed as well as connection surfaces 46, 48 of leads 42, 44. Note that preferably all connection surfaces 46, 48 are coplanar.

Die 36 in a package according to the second embodiment may be a HEMT, a MOSHFET, MISHFET or the like, and may be preferably a III-nitride heterojunction device based on the InAlGan system, for example, a GaN-based device.

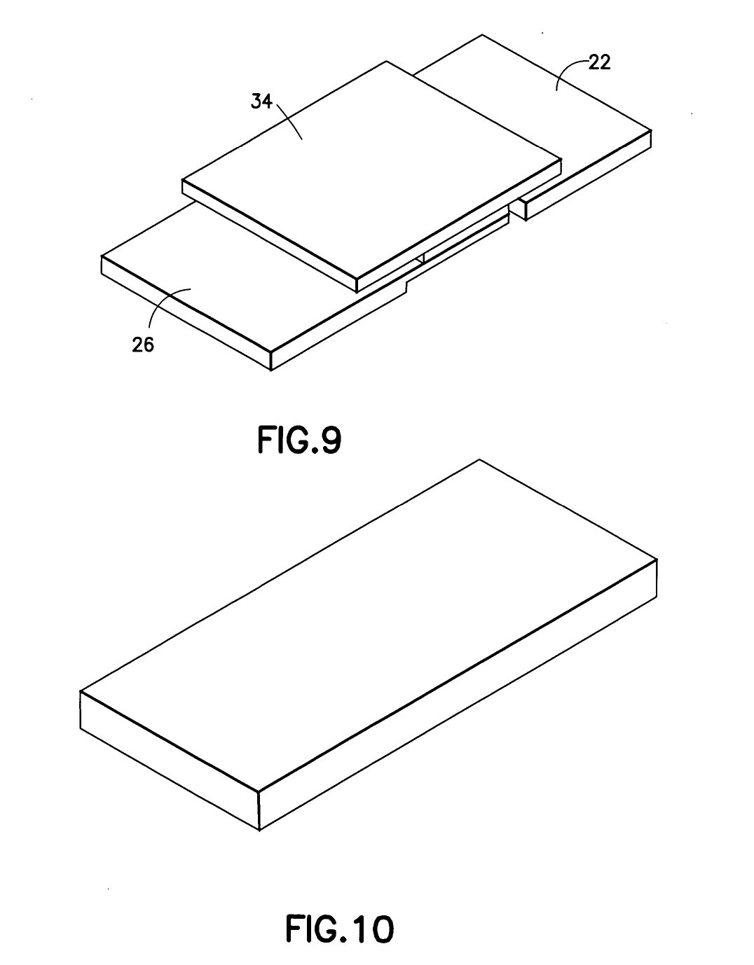

Referring to FIG. 9, optionally a heat spreader 34 can be thermally mounted onto die 36 and in thermal communication therewith prior to housing the same in mold compound. In this example, preferably, heat spreader 34 will be exposed through the molded housing. Alternatively, heat spreader 34 can be omitted in which case mold compound will cover the back of die 36 as illustrated by FIG. 10.

In the preferred embodiment, heat spreader 34 may be made from copper or a copper alloy, while first lead frame portion 16 and second lead frame portion 18 may be made from copper or a copper alloy, and finished with a solderable exterior surface such as nickel.

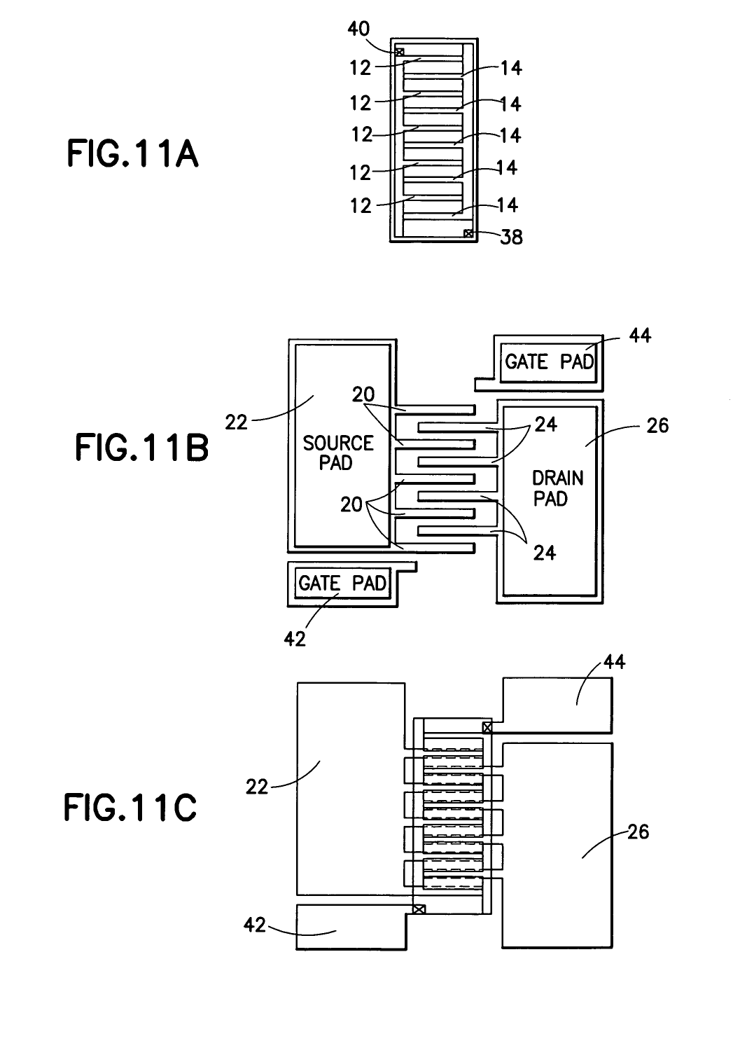

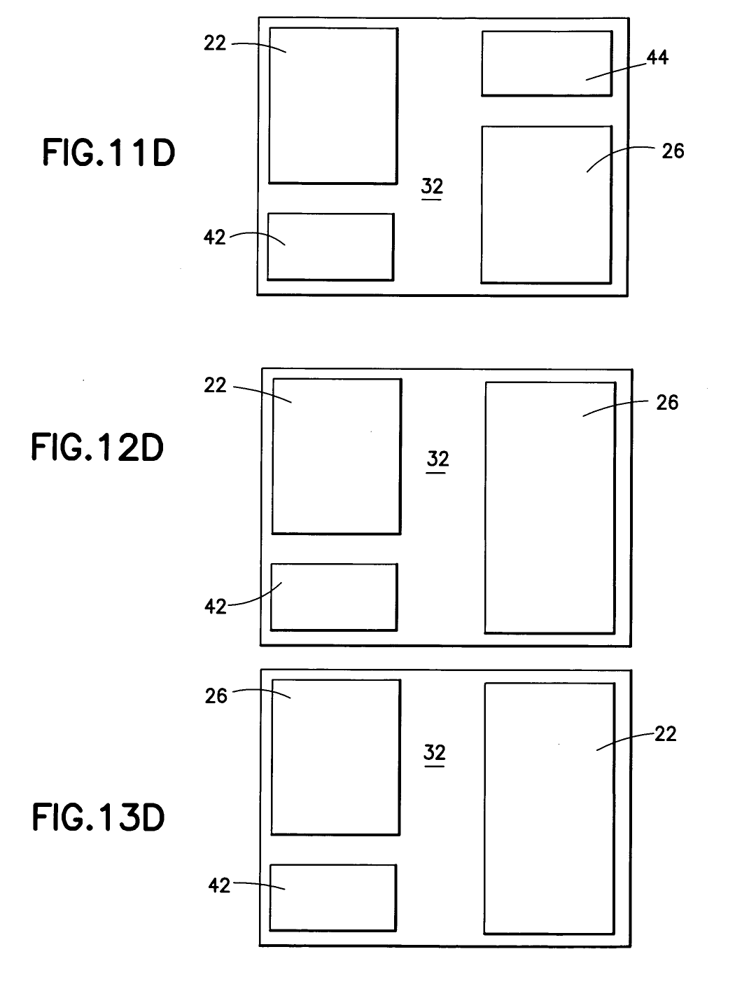

FIGS. 11A-13D illustrate three additional embodiments of a package according to the present invention. FIGS. 11A-11D illustrate a package for a bidirectional device having two gate electrodes 38,40, in which gate pads 42 and 44 are disposed on opposite corners of the package adjacent opposite sides. FIG. 11D illustrates the bottom view of the package after it has been molded over with mold compound.

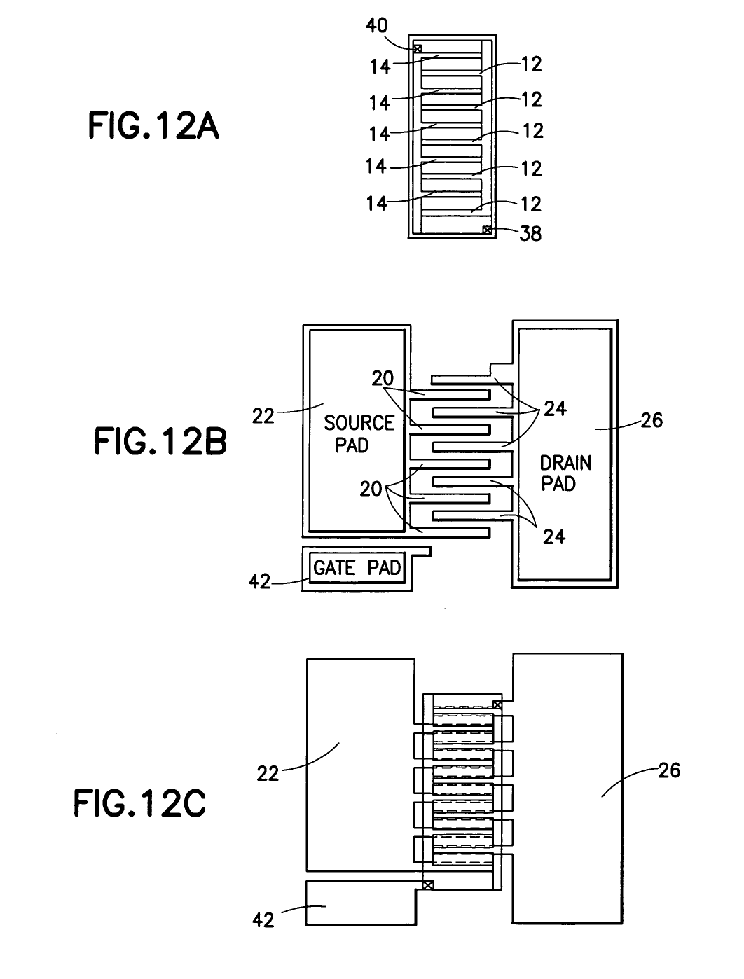

FIGS. 12A-12D illustrate an additional embodiment which includes only one gate pad 42. Note that in this example pad 22 is smaller than pad 26. FIG. 12D illustrates the bottom plan view after over-molding with mold compound.

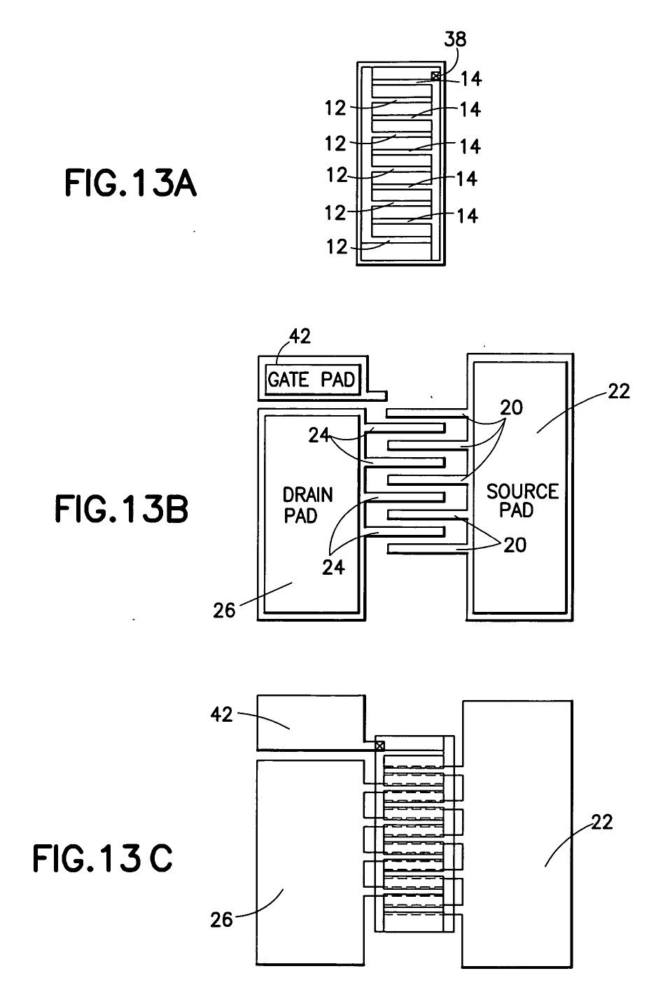

FIGS. 13A-13D illustrate an additional embodiment which also includes only one gate pad 42. Note that in this example pad 26 is smaller than pad 22. FIG. 13D illustrates the bottom plan view after over-molding with mold compound.

Note that for illustration purposes the semiconductor device has been render transparent in FIGS. 11C, 12C, 13C.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A semiconductor package comprising:
a semiconductor die having a first plurality of power electrodes and a second plurality of power electrodes disposed on a major surface thereof, each first power electrode being spaced from and opposite to a second power electrode;
a lead frame including a first lead portion and a second lead portion, said first lead portion including a plurality of spaced first fingers each electrically and mechanically connected to a respective first power electrode and a first lead pad electrically connected to said spaced first fingers and having a first external surface configured for external electrical connection, and said second lead portion including a plurality of spaced second fingers each electrically and mechanically connected to a respective second power electrode and a second lead pad electrically connected to said spaced second fingers and having a second external surface configured for external electrical connection; and
molded housing encapsulating at least said semiconductor die and portions of said first lead pad and said second lead pad, wherein said first external surface and said second external surface are exposed through said molded housing.

2. The package of claim 1, wherein said first external surface and said second external surface are coplanar.

3. The package of claim 1, wherein said semiconductor die is a III-nitride based power semiconductor device.

4. The package of claim 3, wherein said die is a schottky device.

5. The package of claim 3, wherein said die is a HEMT.

6. The package of claim 3, wherein said die is a MOSHFET.

7. The package of claim 3, wherein said die is a MISHFET.

8. The package of claim 1, wherein said semiconductor die further includes a control electrode electrically connected to a control lead having a connection surface exposed through said molded housing.

9. The package of claim 8, wherein said connection surface of said control lead is coplanar with said first and said second external surfaces.

10. The package of claim 1, wherein said semiconductor die further includes a first control electrode electrically connected to a first control lead having a connection surface exposed through said molded housing and a second control electrode electrically connected to a second control lead having a connection surface exposed through said molded housing.

11. The package of claim 10, wherein said connection surfaces of said control leads are coplanar with said first and said second external surfaces.

12. The package of claim 1, wherein said semiconductor die further includes a control electrode electrically connected to a control lead having a connection surface exposed through said molded housing and a current sense electrode electrically connected to a current sense lead having a connection surface exposed through said molded housing.

13. The package of claim 12, wherein said connection surfaces of said control lead and said current sense lead are coplanar with said first and said second external surfaces.

14. The package of claim 1, further comprising a heat spreader thermally connected to said semiconductor die and exposed through said molded housing.

15. The package of claim 14, wherein an exposed surface of said heat spreader is coplanar with an external surface of said molded housing.
